(19) United States
(12) Patent Application Publication
(10) Pub. No.: US 2007/0158821 A1
(43) Pub. Date: Jul. 12, 2007

(54) Managed memory component

(76) Inventors: Leland Szewerenko, Austin, TX (US); James Douglas Wehrly, Austin, TX (US); David L. Roper, Austin, TX (US)

Correspondence Address: FISH & RICHARDSON P.C., P.O BOX 1022, Minneapolis, MN, 55440-1022, US

(21) Appl. No.: 11/482,325

(22) Filed: Jul. 7, 2006

Related U.S. Application Data
(63) Continuation-in-part of application No. 11/330,307, filed on Jan. 11, 2006.
Application No. 11/330,307 is a continuation-in-part of application No. 11/436,946, filed on May 18, 2006.

(51) Int. Cl. H01L 23/12

(52) U.S. Cl. 257/700

(57) ABSTRACT

The present invention provides a system and method for combining a leaded package IC and a semiconductor die using a flex circuitry. The leaded packaged IC is disposed along one side of a flex circuit. The semiconductor die is disposed along the flex circuitry and preferably is between at least a part of the flex circuitry and the body of the leaded packaged IC. Preferably, the die is attached to a conductive layer of the flex circuitry. The flex circuitry preferably employs at least two conductive layers and the leaded packaged IC and die are preferably connected to one of the conductive layers of the flex circuitry. In preferred modules, the leaded packaged IC is preferably a flash memory device and the semiconductor die is preferably a controller.

### RELATED APPLICATIONS

The present application is a continuation-in-part of U.S. patent application Ser. No. 11/332,307, filed Jan. 11, 2006, pending and a continuation-in-part of U.S. patent application Ser. No. 11/436,946, filed May 18, 2006, pending, both of which applications are hereby incorporated by reference.

### TECHNICAL FIELD

This invention relates to integrated circuit modules and, in particular, to integrated circuit modules that provide memory and controller in a compact footprint module.

### BACKGROUND

A variety of systems and techniques are known for combining integrated circuits in compact modules. Some techniques are suitable for combining packaged integrated circuits while other techniques are suitable for combining semiconductor die. Many systems and techniques employ flex circuitry as a connector between packaged integrated circuits in, for example, stacks of packaged leaded or chip-scale integrated circuits. Other techniques employ flex circuitry to “package” semiconductor die and function as a substitute for packaging.

Within the group of technologies that stack packaged integrated circuits, some techniques are devised for stacking chip-scale packaged devices (CSPs) while other systems and methods are better directed to leaded packages such as those that exhibit a set of leads extending from at least one lateral side of a typically rectangular package.

Integrated circuit devices (ICs) are packaged in both chip-scale (CSP) and leaded packages. However, techniques for stacking CSP devices are typically not optimum for stacking leaded devices, just as techniques for leaded device stacking are typically not suitable for CSP devices. Few technologies are, however, directed toward combining packaged integrated circuits with semiconductor die.

Although CSP devices are gaining market share, in many areas, integrated circuits continue to be packaged in high volumes in leaded packages. For example, the well-known flash memory integrated circuit is typically packaged in a leaded package with fine-pitched leads emergent from one or both sides of the package. A common package for flash memory is the thin small outline package commonly known as the TSOP typified by leads emergent from one or more (typically a pair of opposite sides) lateral sides of the package.

Flash memory devices are gaining wide use in a variety of applications. Typically employed with a controller for protocol adaption, flash memory is employed in solid state memory storage applications that are supplanting disk drive technologies. However, when flash memory is employed with controller logic, the application footprint typically expands to accommodate the multiple devices required to provide a module that is readily compatible with most memory subsystem interface requirements. Consequently, what is needed is a memory module that includes a controller logic and flash memory storage without substantial increases in footprint or thickness.

### SUMMARY OF THE INVENTION

The present invention provides a system and method for combining a leaded package IC and a semiconductor die using a flex circuitry. The leaded packaged IC is disposed along one side of a flex circuit. The semiconductor die is disposed along the flex circuitry and preferably is disposed between at least one layer of the flex circuitry and the body of the leaded packaged IC. Preferably, the die is attached to a conductive layer of the flex circuitry which preferably employs at least two conductive layers. The leaded packaged IC and die are preferably connected to one of the conductive layers of the flex circuitry. In preferred modules, the leaded packaged IC is a flash memory device and the semiconductor die is a controller.

### BRIEF DESCRIPTION OF THE DRAWINGS

FIG. 1 is a side cross-sectional view of an exemplar module devised in accordance with a preferred embodiment of the present invention.

FIG. 2 depicts an alternative embodiment in accordance with the present invention.

FIG. 3 depicts an alternative embodiment in which the leads of a leaded packaged IC penetrate the flex circuitry employed in a module in accordance with a preferred embodiment of the present invention.

FIG. 4 depicts an alternative embodiment in accord with the present invention in which lead holes are present in the flex circuitry.

FIG. 5 depicts yet another embodiment in accordance with the present invention in which an area of flex circuitry is deflected.

FIG. 6 depicts yet another embodiment for connecting the leaded packaged IC to the flex-circuitry in accordance with the present invention.

FIG. 7 depicts an alternative embodiment of the present invention in which flex circuitry has distal ends that contact an inner side of the leads of the leaded packaged IC.

FIG. 8 depicts an enlarged cross-sectional view of a circuit module devised in accordance with a preferred embodiment of the present invention illustrating the area marked “A” in FIG. 1.

### DETAILED DESCRIPTION

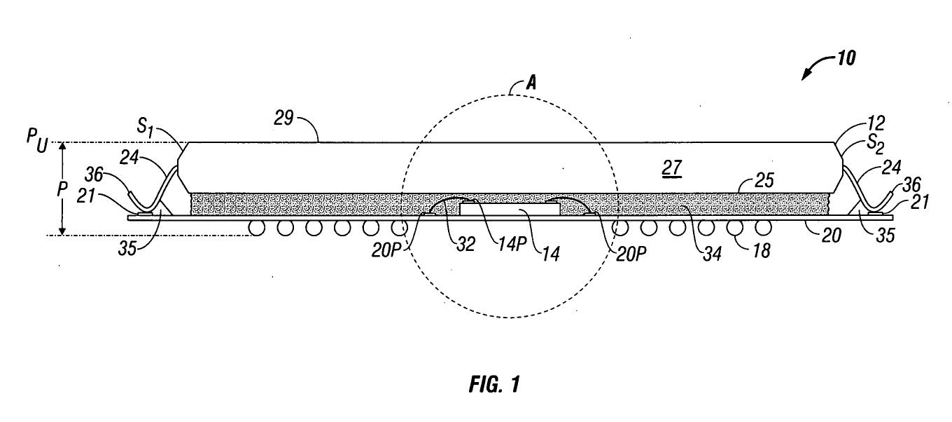

FIG. 1 is a side cross-sectional view of an exemplar module 10 devised in accordance with a preferred embodiment of the present invention. Exemplar module 10 is comprised of leaded packaged IC 12 and semiconductor die 14 each connected to flex circuitry 20. In preferred embodiments, leaded packaged IC 12 is a flash memory device and semiconductor die 14 is a controller. In a preferred embodiment, semiconductor die 14 is covered by an encapsulate 34 disposed between the body of leaded packaged IC 12 and flex circuitry 20 as shown. In this embodiment, module contacts 18 are shown disposed along side 9 of flex circuitry 20 while leaded packaged IC 12 is disposed on side 8 of flex circuitry 20. Semiconductor die 14 (die 14) is preferably attached to a conductive layer of the flex circuitry and attached with die attach 14DA as shown later in greater detail.

Flex circuitry 20 is preferably comprised from multiple layers including one or more conductive layers supported by one or more flexible substrate layers and is preferably comprised with two conductive layers although more layers are commensurate with the invention as well. Flex circuitry with one conductive layer could also be devised to be employed with some embodiments of the invention.

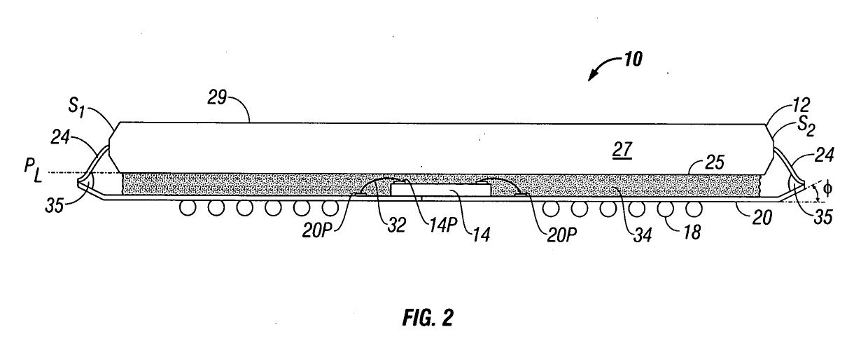

As shown, leaded packaged IC 12 has a body 27 with an upper side 29 and lower side 25 and is connected to flex circuitry 20 through leads 24 that are connected to leaded IC pads 21 which are, in many but not all embodiments, located along side 8 of flex circuitry 20. In some embodiments, however, leaded packaged IC 12 is connected to side 9 of flex circuitry 20 as will be later shown. As those of skill will recognize, many techniques exist for connecting the leads of leaded packaged IC 12 to flex circuitry 20 including leaded pads 21. Such techniques include, as a non-limiting example, use of solder such as solder 35 shown in FIGS. 1 and 2. Other forms of bonding other than solder between leaded IC pads 21 and leads 24 may also be employed (such as brazing, welding, tab bonding, or ultrasonic bonding, just as examples) but soldering techniques are well understood and adapted for use in large scale manufacturing. Leads 24 typically but not always, exhibit feet 36. Later views will show embodiments in which leads 24 do not exhibit feet 36. Leads 24 may be connected to either or both of the sides of flex circuitry 20 as will be later shown.

Preferably encapsulate 34 is used between body 27 of leaded packaged IC 12 and flex circuit 20. An adhesive may also be employed between IC 12 and flex circuitry 20. Module contacts 18 are, in the depicted embodiment, balls such as those found in ball grid array (BGA) devices but other types of module contacts 18 may be employed in embodiments of the present invention.

As shown in FIGS. 1 and 2, leaded packaged IC 12 exhibits lateral sides S1 and S2 which, as those of skill will recognize, may be in the character of edges or sides and need not be perpendicular in aspect to the upper and lower surfaces 29 and 25, respectively. Leads 24 are emergent from sides S1 and S2 in the depicted leaded packaged IC 12 but those of skill will note that some leaded packaged ICs may have leads emergent from only one side or more than two sides. In the embodiment depicted in FIG. 1, leads 24 have preferably be re-configured to deflect feet 36 toward plane PU defined by upper surface 29 to allow flex circuitry 20 to preferably present a planar aspect across its extent as shown in FIG. 1.

In FIG. 2, an alternative embodiment is shown in which leads 24 are not reconfigured and flex circuitry 20 is deflected toward lower plane PL which is coincident with lower surface 25 of leaded packaged IC 12. The deflected area of flex circuitry 20 bears the plural leads of leaded packaged IC 12 and the degree of such deflection is indicated by the reference φ.

Reconfiguration (e.g., modification, reforming) of the leads is one option that may be employed where there is a desire to not modify the flex circuitry from a planar disposition while still creating a module with a low profile. Although not preferred, higher thicknesses of adhesive and or encapsulate will also avoid lead re-configuration as will a variety of the exemplar options shown in later Figs herein.

Reconfiguration, if undertaken, is preferably performed before mounting of the leaded IC 12 to flex circuit 20. Those of skill will note that a preferred method for reconfiguration of leads 24, if desired, comprises use of a jig to fix the position of body 27 of the leaded packaged IC and, preferably, support the lead at the point of emergence from the body at sides S1 and S2 before deflection of the respective leads toward the upper plane PU. This is because typically, leaded packaged ICs such as TSOPs are configured with leads that extend substantially beyond the lower plane PL shown in FIG. 2.

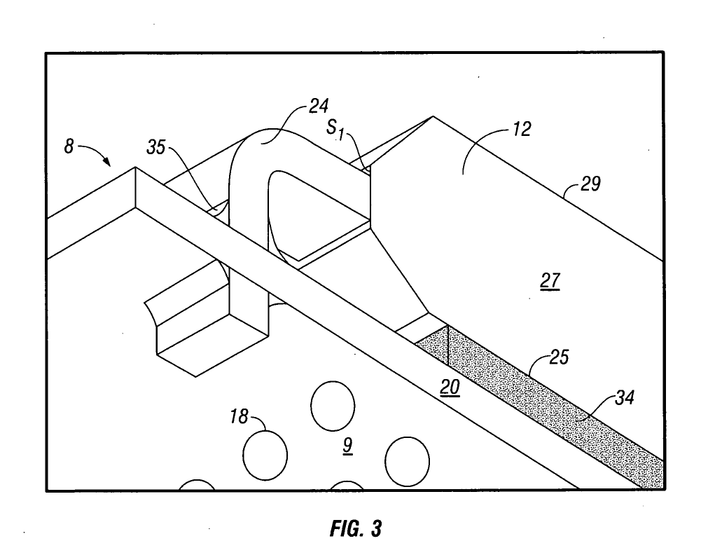

In FIG. 3, as an alternative configuration between leaded packaged IC 12 and flex circuitry 20, leaded packaged IC 12 is shown with a lead 24 that penetrates flex circuitry 20 and is connected to both sides 9 and 8 of flex circuitry 20 with solder 35.

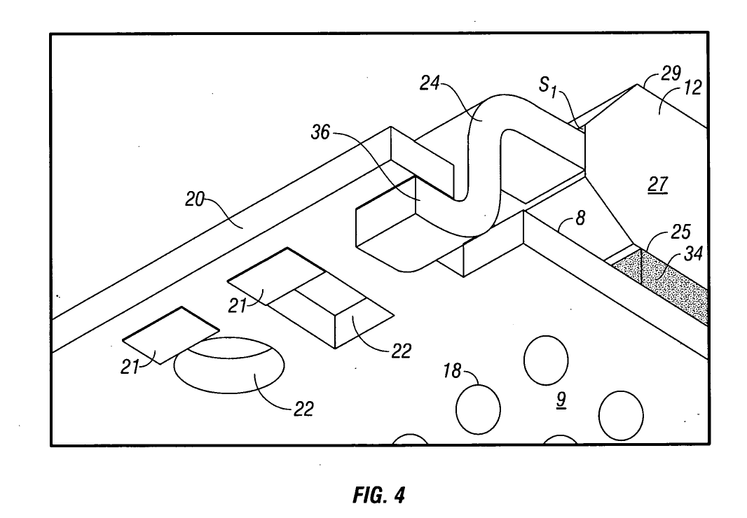

FIG. 4 depicts an alternative embodiment in accord with the present invention in which flex circuitry 20 exhibits lead holes 22 through which leads 24 project so that leads 24 may be connected to leaded IC pads 21 which, in this instance, are on side 9 of flex circuitry 20 rather than side 8 as depicted in several other Figs. This strategy may result in a lower profile P for module 10 without resort to reconfiguration of leads 24.

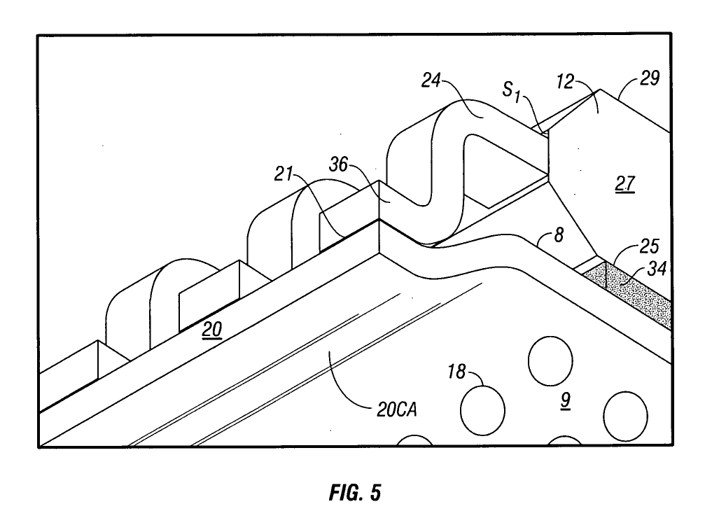

FIG. 5 depicts yet another technique for connection of leaded packaged IC 12 to flex circuitry 20. As shown in FIG. 5, in this embodiment as opposed to the embodiment of FIG. 2, area 20CA of flex circuitry 20 is deflected away to allow leads 24 and in particular, feet 36 of leads 24 to be connected to leaded IC pads 21 on side 8 of flex circuitry 20.

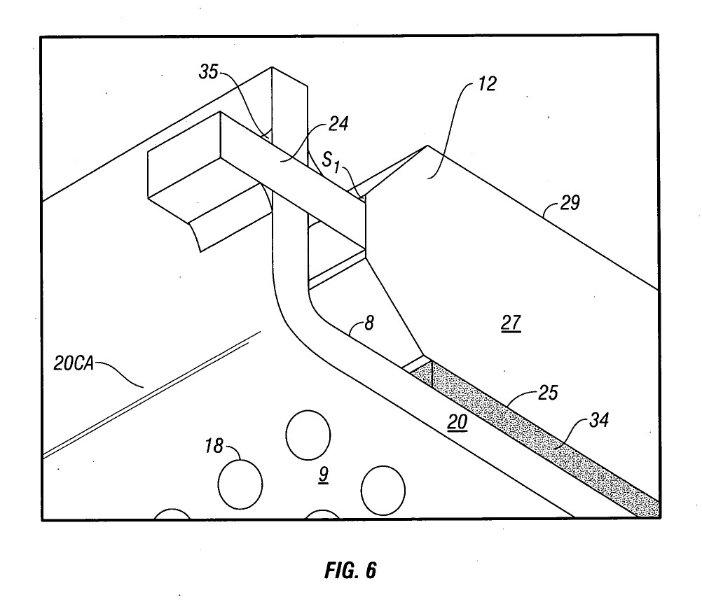

FIG. 6 depicts yet another technique for connecting leaded packaged IC 12 to flex circuitry 20. In the embodiment depicted in FIG. 6, leads 24 penetrate deflected area 20CA of flex circuitry 20 which, in this embodiment, is deflected toward the body 27 of leaded packaged IC 12 rather than away from leaded packaged IC 12 as shown in earlier FIG. 5. In this depiction, leads 24 are connected to both sides 9 and 8 of flex circuitry 20. Leads 24 are also parallel with lower major surface 25 as shown. Lower major surface 25 of leaded packaged IC is in contact with encapsulate 34 which, in turn, is in contact with flex circuitry 20.

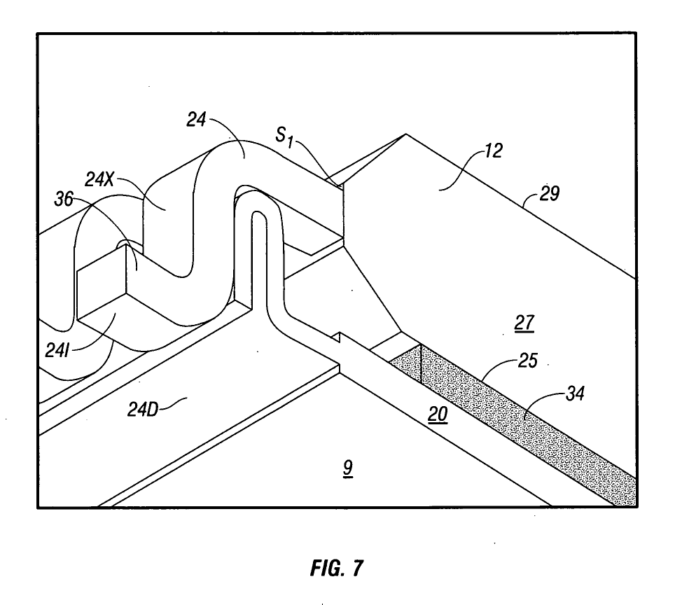

FIG. 7 depicts an alternative embodiment of the present invention in which flex circuitry 20 has distal ends 20D that are deflected to contact inner side 24I of leads 24 which have, as shown, an inner side 24I and an external side 24X.

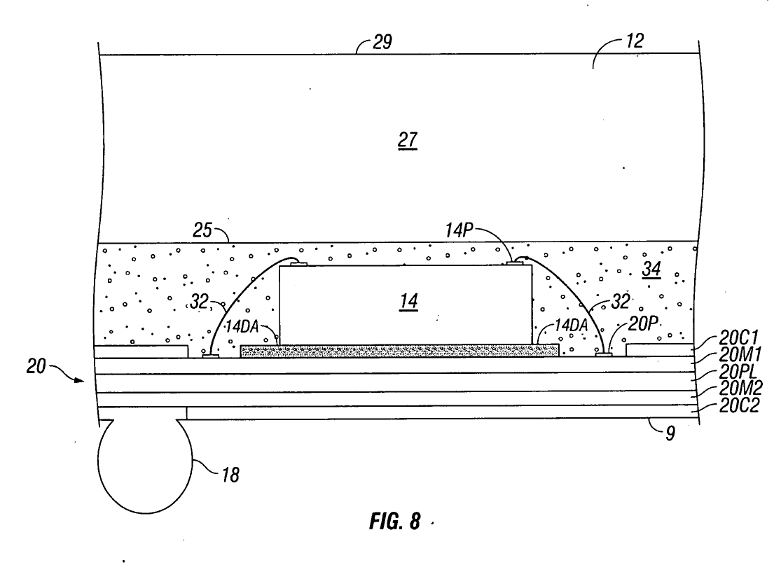

FIG. 8 is a perspective view of a module devised in accordance with an embodiment of the present invention. As depicted, semiconductor die 14 is connected through wire bonds 32 to flex circuit 20. Wire bonds 32 are attached to flex pads 20P of flex circuitry 20. Concurrently, leaded packaged IC 12 is connected to flex circuitry 20 through leads 24. Die 14 is shown encapsulated by encapsulate 34. A variety of methods can be employed to effectuate the encapsulation of die 14 and such methods are known to those of skill in the art.

FIG. 8 also depicts details on-a preferred flex circuitry 20 that exhibits multiple layers including at least two conductive layers identified in FIG. 8 as 20M1 and 20M2 which, in this embodiment, are separated by a polyimide layer 20PL. Conductive layers 20M1 and 20M2 are typically copper that has been plated with emersion nickel gold or emersion nickel silver or organic surface protection where needed. In a preferred embodiment, pads 21 shown earlier are connected to layer 20M1. Thus, those of skill will recognize that die 14 and leaded packaged IC 12 are connected to the same conductive layer. There are, as those of skill will recognize, alternative embodiments in which leaded packaged IC 12 is connected to a conductive layer of flex circuitry 20 different from that to which die 14 is connected. Optional covercoat 20C1 is shown along with covercoat 20C2 which also is optional. Covercoats on flex circuitry are well understood by those of skill in the art. Conductive layers in flex circuitry are well understood in the art and typically comprise a network of connections that allow interconnections between various components to be realized through the conductive layers.

As illustrated, semiconductor die 14 is attached to conductive layer 20M1 through die attach 14DA. Attached to layer 20M1 through die attach 20DA, semiconductor die 14 is electrically connected to layer 20M1 through wire bonds 32 that extend between die pads 14P and flex pads 20P of layer 20M1. Flex pads 20P are depicted in the cross-sectional view of FIG. 8 as rising above layer 20M1 but, as those of skill recognize, these are shown with elevated profile for heuristic purposes and in practice are typically a part of layer 20M1 and would be indistinguishable in this view. Conductive layer 20M1 can function as a heat spreader for semiconductor die 14, depending on the actual layout of layer 20M1 as those of skill will recognize.

FIG. 8 also shows an exemplar module contact 18. As those of skill will recognize, the depiction of module contact 18 is merely representative and the placement, configuration and exact size of the plural module contacts 18 that typically are employed in a module 10 may be varied to fit the needs of the application.

The present invention may also be employed with circuitry other than or in addition to memory such as the flash memory depicted in a number of the present Figs. Other exemplar types of circuitry that may be aggregated in accordance with embodiments of the invention include., just as non-limiting examples, DRAMs, FPGAs, and system stacks that include logic and memory as well as communications or graphics devices. It should be noted, therefore, that the depicted profile for leaded packaged IC 12 is not a limitation and that leaded packaged IC 12 does not have to be a TSOP or TSOP-like and the package employed may have more than one die or leads emergent from one, two, three or all sides of the respective package body. Leaded packaged IC 12 may also have a cutout area on the underside of its body into which the semiconductor die may fit to further reduce the profile of module 10. A module 10 in accordance with embodiments of the present invention may further employ a leaded packaged IC 12 that has more than one die within the package and may exhibit leads emergent from only one side of the package.

It will be seen by those skilled in the art that many embodiments taking a variety of specific forms and reflecting changes, substitutions, and alternations can be made without departing from the spirit and scope of the invention. Therefore, the described embodiments illustrate but do not restrict the scope of the claims.

1. A circuit module comprising:
flex circuitry having first and second sides, the flex circuitry having a plurality of leaded IC pads and the second side of the flex circuitry having an array of module contacts, the flex circuitry comprising multiple layers including plural conductive layers;
a leaded packaged IC having a body and upper and lower major surfaces, plural peripheral sides, and leads emergent from at least a first one of the plural peripheral sides of the leaded packaged IC, the leads being connected to the flex circuitry through the plurality of leaded IC pads; and
a semiconductor die attached to a selected one of the plural conductive layers of the flex circuitry and which semiconductor die is electrically connected to a first one of the plural conductive layers of the flex circuitry and disposed between the body of the leaded packaged IC and at least a selected one of the multiple layers of the flex circuitry.

2. The circuit module of claim 1 in which the leaded package IC is connected to the first one of the plural conductive layers of the flex circuitry.

3. The circuit module of claim 1 in which the semiconductor die is closer to the body of the leaded packaged IC than is the second conductive layer of the flex circuitry.

4. The circuit module of claims 1 or 2 in which the semiconductor die is between a second one of the plural conductive layers of the flex circuitry and the body of the leaded packaged IC.

5. The circuit module of claims 1 or 4 in which the leaded packaged IC is a flash memory circuit.

6. The circuit module of claims 1 or 4 in which the semiconductor die is a controller.

7. The circuit module of claim 1 in which the semiconductor die is attached to the first one of the plural conductive layers.

8. The circuit module of claim 1 in which the semiconductor die is attached to the second one of the plural conductive layers.

9. The circuit module of claim 1 in which the semiconductor die is electrically connected to a selected one of the plural conductive layers with wire bonds.

10. The circuit module of claims 1 or 4 in which encapsulate is disposed between the body of the leaded packaged IC and the semiconductor die.

11. The circuit module of claim 10 in which the semiconductor die is encapsulated.

12. The circuit module of claim 10 in which the leaded packaged IC is a flash memory device and the semiconductor die is a controller.

13. The circuit module of claim 10 in which the semiconductor die is electrically connected to the flex circuitry with wire bonds.

14. The circuit module of claim 1 in which the plurality of leaded IC pads are accessible from the first side of the flex circuitry.

15. The circuit module of claim 1 in which the plurality of leaded IC pads are accessible from the second side of the flex circuitry.

16. The circuit module of claim 1 in which the leads of the leaded packaged IC are parallel to the lower major surface of the leaded packaged IC.

17. The circuit module of claim 1 in which the leads of the leaded packaged IC are connected to the first and second sides of the flex circuitry.

18. The circuit module of claim 1 in which the flex circuitry further comprises a deflected area where the leaded packaged IC is connected to the flex circuitry.

19. The circuit module of claim 1 in which the flex circuitry further comprises a deflected area that is deflected toward the body of the leaded packaged IC.

20. The circuit module of claim 1 in which the flex circuitry exhibits lead holes through which each of the leads projects to contact the plurality of leaded IC pads.

21. The circuit module of claim 1 in which the flex circuitry has at least one distal end that contacts an inner side of one of the leads of the leaded packaged IC.

22. The circuit module of claim 1 in which at least one of the leads passes through the flex circuitry.

23. A circuit module comprising:
flex circuitry having first and second sides, the flex circuitry having a plurality of leaded IC pads and the second side of the flex circuitry having an array of module contacts, the flex circuitry comprising multiple layers including at least one conductive layer;
a leaded packaged IC having a body and upper and lower major surfaces, plural peripheral sides, and leads emergent from at least a first one of the plural peripheral sides of the leaded packaged IC, the leaded packaged IC being disposed on the first side of the flex circuitry and the leads being connected to the flex circuitry; and
a semiconductor die attached to the at least one conductive layer of the flex circuitry so that the semiconductor die is between the body of the leaded packaged IC and at least one of the multiple layers of the flex circuitry.

24. The circuit module of claim 23 in which the leaded packaged IC is a flash memory device and the semiconductor die is a controller.

25. The circuit module of claim 23 in which encapsulate is disposed between the flex circuitry and the body of the leaded packaged IC.

26. The circuit module of claim 24 in which encapsulate is disposed between the flex circuitry and the body of the leaded packaged IC.

27. The circuit module of claim 23 in which the flex circuitry further comprises a deflected area where the leaded packaged IC is connected to the flex circuitry.

28. The circuit module of claim 23 in which the flex circuitry further comprises a deflected area that is deflected toward the body of the leaded packaged IC.

29. The circuit module of claim 23 in which the flex circuitry further comprises a deflected area that is deflected away from the body of the leaded packaged IC.
